(19) United States
(12) Patent Application Publication
(10) Pub. No.: US 2025/0203730 A1
(43) Pub. Date: Jun. 19, 2025

(54) TEST DEVICE AND TEST METHOD

(71) Applicant: Tokyo Electron Limited, Tokyo (JP)

(72) Inventors: Shigeru KASAI, Yamanashi (JP); Fumiya TAKASE, Yamanashi (JP)

(21) Appl. No.: 18/847,761

(22) PCT Filed: Mar. 16, 2023
(86) PCT No.: PCT/JP2023/010307

§ 371 Date: Sep. 17, 2024

(30) Foreign Application Priority Data
Mar. 30, 2022 (JP) 2022-056610

(51) Int. Cl. H05B 45/3725; G01R 31/308; H05B 45/345

(52) U.S. Cl. CPC H05B 45/3725; G01R 31/308; H05B 45/345

(57) ABSTRACT

A test device includes a mounting table configured to mount a substrate; an irradiation device configured to irradiate the substrate mounted on the mounting table with test light; a tester configured to test the substrate that has received the test light. The irradiation device includes a light emitting section in which a plurality of LEDS are connected; a fixed power supply configured to output power to be supplied to the light emitting section; and a constant current section provided between the light emitting section and the fixed power supply. The fixed power supply includes a plurality of switching power supplies configured to perform switching using a resonance phenomenon. The constant current section includes a first constant current source and a second constant current source connected in parallel, the first constant current source being configured to receive the power of the plurality of switching power supplies and adjust a current in a first resolution, and the second constant current source being configured to receive the power of the plurality of switching power supplies and adjust a current in a second resolution less than the first resolution.

### TECHNICAL FIELD

The present disclosure relates to a test device and a test method.

### BACKGROUND

In a test of a substrate including multiple image sensors, the presence or absence of a defect in each of picture elements of the image sensors is determined by irradiating the substrate with test light from a light emitting section formed by multiple LEDs. In recent years, a test device including a light emitting section on a mounting table side where a substrate is mounted has been developed for the reason of improvement in S/N ratio, reduction in power consumption, and the like. For example, Patent Document 1 discloses a test device including a light irradiation mechanism (an irradiation device) configured to irradiate a substrate including multiple image sensors with test light from a mounting table side.

### RELATED ART DOCUMENT

### Patent Document

[Patent Document 1] Japanese Laid-open Patent Application Publication No. 2019-106491

### SUMMARY OF THE INVENTION

### Problem to be Solved by the Invention

The present disclosure provides a technique of suppressing power loss of an irradiation device and adjusting the amount of light in a wide range and with high accuracy in a test of a substrate.

### Means for Solving the Problem

According to one aspect of the present disclosure, a test device that tests a substrate, and includes a mounting table configured to mount the substrate; an irradiation device provided in the mounting table and configured to irradiate the substrate mounted on the mounting table with test light; and a tester configured to test the substrate that has received the test light is provided. The irradiation device includes a light emitting section in which a plurality of LEDs are connected; a fixed power supply configured to output power to be supplied to the light emitting section; and a constant current section provided between the light emitting section and the fixed power supply and configured to adjust an amount of a current based on a voltage input from the fixed power supply and supply the current to the light emitting section. The fixed power supply includes a plurality of switching power supplies configured to perform switching using a resonance phenomenon. The constant current section includes a first constant current source and a second constant current source connected in parallel, the first constant current source being configured to receive the power of the plurality of switching power supplies and adjust a current to be supplied to the light emitting section in a first resolution, and the second constant current source being configured to receive the power of the plurality of switching power supplies and adjust a current to be supplied to the light emitting section in a second resolution less than the first resolution.

### Effect of the Invention

According to one aspect, in a test of a substrate, power loss of an irradiation device can be suppressed and the amount of light can be adjusted in a wide range with high accuracy.

### BRIEF DESCRIPTION OF THE DRAWINGS

FIG. 1 is a schematic vertical cross-sectional view illustrating a configuration of a test device according to an embodiment.

FIG. 2A is a side cross-sectional view schematically illustrating a configuration of a mounting table and an irradiation device.

FIG. 2B is a plan view schematically illustrating the configuration of the mounting table and the irradiation device.

FIG. 3 is an explanatory diagram schematically illustrating a configuration of a supply circuit of the irradiation device.

FIG. 4A is a circuit diagram illustrating a configuration of a switching power supply.

FIG. 4B is a waveform diagram of a hard-switch power supply with no capacitor at turn-off.

FIG. 4C is a waveform diagram of a hard-switch power supply with a capacitor at turn-off.

FIG. 5 is a block diagram illustrating functional blocks of a main controller configured to control the irradiation device.

FIG. 6 is a flowchart illustrating a test method according to the embodiment.

FIG. 7 is an explanatory diagram schematically illustrating a supply circuit of an irradiation device according to a modified example.

### DESCRIPTION OF THE EMBODIMENTS

In the following, embodiments for implementing the present disclosure will be described with reference to the drawings. In the drawings, the same components are denoted by the same reference symbols, and a duplicate description thereof may be omitted.

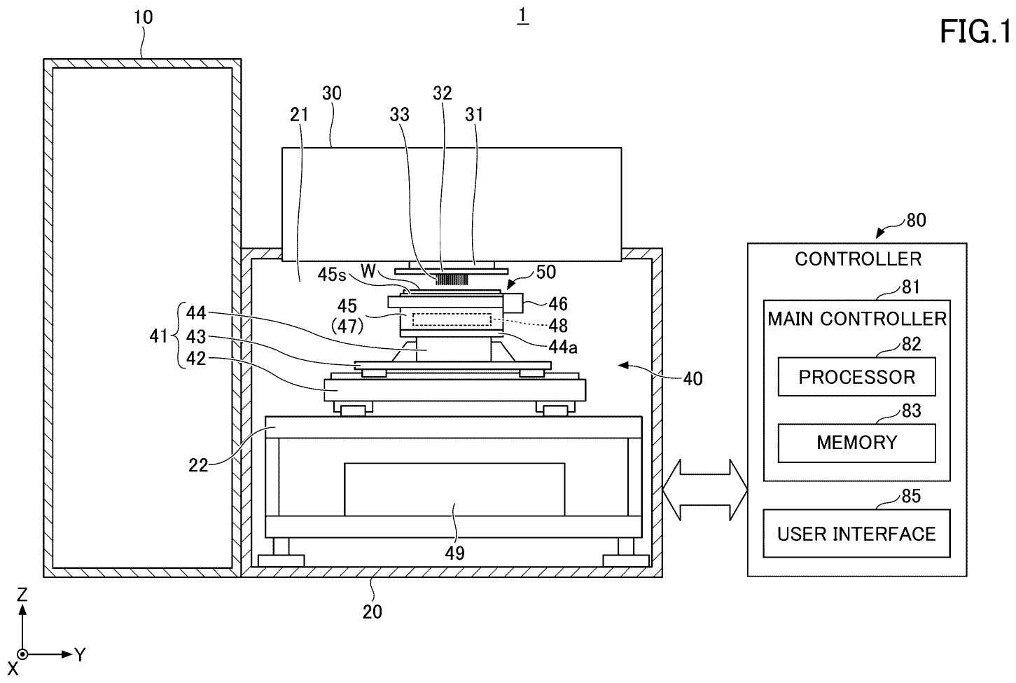

FIG. 1 is a schematic vertical cross-sectional view illustrating a configuration of a test device 1 according to an embodiment. As illustrated in FIG. 1, the test device 1 according to the embodiment performs an optical test on a substrate including multiple image sensors (not illustrated), which are test target devices. Examples of the image sensor of the test target device include a complementary metal oxide semiconductor (CMOS) sensor. Additionally, the substrate is formed in a circle shape in plan view, and multiple image sensors are arranged in a matrix (hereinafter, the substrate is also referred to as a wafer W). Here, the substrate is not limited to the wafer W including multiple image sensors, and may be a carrier, a single chip, an electronic circuit board, or the like on which an image sensor is arranged.

Each of the image sensors has multiple picture elements corresponding to the resolution, and each of the picture elements has a stacked structure in which an on-chip lens, a color filter, a photodiode, and a wiring layer are stacked in this order. In other words, the image sensor is configured as a backside illumination type imaging semiconductor device in which the photodiode is disposed on the on-chip lens side (on the incidence side). The wiring layer of the image sensor includes multiple wirings for inputting an electric signal to a circuit element in the image sensor and outputting an electric signal from the circuit element.

In the test, the test device 1 mounts the wafer W with the surface on the on-chip lens side facing a stage 40, and moves the stage 40 to bring a probe 33 into contact with the wiring of the wiring layer of each of the image sensors. Further, the test device 1 emits light for test (hereinafter, referred to as test light), of which color, light amount (radiation intensity), angle, and the like are controlled, from an irradiation device 50 on the stage 40 side toward the wafer W. The test device 1 receives an electric signal of each of the image sensors at the time of the irradiation by a tester 30, and determines whether each of the image sensor is in a good condition or defective.

Here, each of the multiple picture elements may include multiple photodiodes for receiving light of multiple colors (for example, RGB) or may include one photodiode for receiving light of a single color. Additionally, the irradiation device 50 may be configured to emit the test light of a single color (for example, white) or may be configured to emit the test light of each of multiple colors (for example, red, green, and blue) when a photodiode that receives multiple colors is tested. Hereinafter, for easy understanding of the invention, first, the irradiation device 50 that emits the test light of a single color will be described.

The test device 1 includes a loader 10 configured to transfer the wafer W, a housing 20 disposed adjacent to the loader 10, the tester 30 disposed above the housing 20, the stage 40 accommodated in the housing 20, and a controller 80 configured to control each component of the test device 1.

The loader 10 takes out the wafer W from a front opening unified pod (FOUP), which is not illustrated, and mounts the wafer W on the stage 40 that has moved in the housing 20. Additionally, the loader 10 takes out the tested wafer W from the stage 40 and accommodates the wafer W in the FOUP.

The housing 20 is formed in a substantially cuboid box shape and has a test space 21 inside, in which the wafer W is tested. The stage 40 for transferring the wafer W is provided at the lower side of the test space 21. The wafer W mounted on the stage 40 from the loader 10 in the test space 21 is moved in three dimensional directions (the X-axis direction, the Y-axis direction, and the Z-axis direction) by the operation of the stage 40, and the rotational coordinate 0 is adjusted.

A probe card 32 is held in an upper portion of the housing 20 via an interface 31. The interface 31 includes a performance board and a large number of connection terminals, which are not illustrated, and is electrically connected to the tester 30 via a test head (not illustrated). The tester 30 is connected to the controller 80 of the test device 1 and tests the wafer W under commands of the controller 80.

The probe card 32 has multiple probes 33 (probing needles) protruding toward a lower portion of the test space 21. In the test of the test device 1, each of the probes 33 comes into contact with the wiring (including pads and solder bumps) of each of the image sensors of the wafer W that moves to an appropriate three-dimensional coordinate position by the stage 40. In such a contact state, the test device 1 performs an optical test on each of the image sensors. Additionally, the controller 80 sequentially repeats the test of the image sensors while moving the stage 40 in the X-axis direction, the Y-axis direction, and the Z-axis direction to shift the position on the wafer W and rotating by θ, thereby testing all the image sensors.

The stage 40 includes a mover 41 (an X-axis movement mechanism 42, a Y-axis movement mechanism 43, and a Z-axis movement mechanism 44) configured to move in the X-axis direction, the Y-axis direction, and the Z-axis direction, a mounting table 45, and a stage controller 49. The housing 20 includes a frame structure 22 that supports the mover 41 and the mounting table 45 of the stage 40 and the stage controller 49 in two stages, that is, upper and lower stages. The mover 41 moves the mounting table 45 in the X-axis direction, the Y-axis direction, and the Z-axis direction based on the power supply from the stage controller 49. Here, the mover 41 has a configuration of rotating the mounting table 45 around an axis (in a @ direction) in addition to moving the mounting table 45 in the X-axis direction, the Y-axis direction, and the Z-axis direction.

The mounting table 45 is a device on which the wafer W is directly mounted, and holds the wafer W on a mounting surface 45s by an appropriate holding means. Examples of the holding means include a suction device 46 configured to vacuum-suction the wafer W to the mounting surface 45s. Further, the mounting table 45 includes the irradiation device 50 configured to irradiate the wafer W with the test light. The configurations of the mounting table 45 and the irradiation device 50 will be described later in detail.

The stage controller 49 is connected to the controller 80 and controls the operation of the stage 40 based on a command from the controller 80. The stage controller 49 includes, for example, an integrated controller configured to control the operation of the entire stage 40, a PLC or a motor driver configured to control the operation of the mover 41, a power supply, and the like (none of which are illustrated).

The controller 80 includes a main controller 81 configured to control the entire test device 1 and a user interface 85 connected to the main controller 81. The main controller 81 is configured by a computer, a control circuit board, or the like.

For example, the main controller 81 includes a processor 82, a memory 83, and an input/output interface and an electronic circuit, which are not illustrated. The processor 82 is one of or a combination of a central processing unit (CPU), a graphics processing unit (GPU), an application specific integrated circuit (ASIC), a field-programmable gate array (FPGA), a circuit including multiple discrete semiconductors, and the like. The memory 83 is an appropriate combination of a volatile memory and a nonvolatile memory (for example, a compact disc, a digital versatile disc (DVD), a hard disk, a flash memory, or the like).

With respect to the above, a keyboard with which the user performs an input operation of a command or the like, and a display that visualizes and displays an operation state of the test device 1 can be applied to the user interface 85. Alternatively, a device, such as a touch panel, a mouse, a microphone, or a speaker, can be applied to the user interface 85.

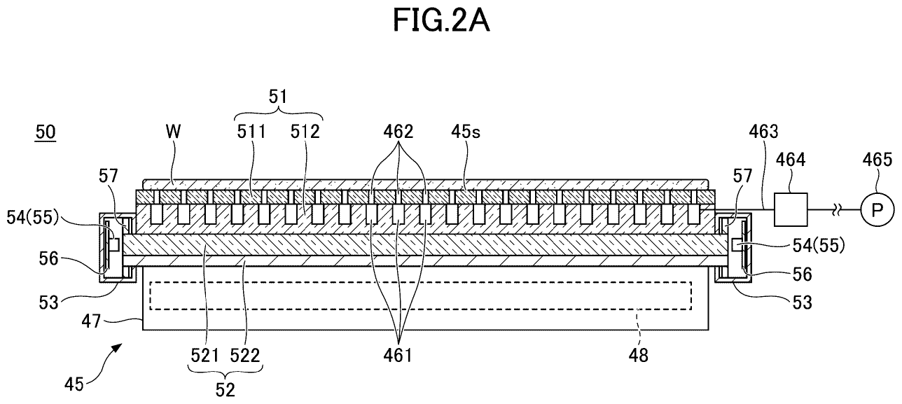

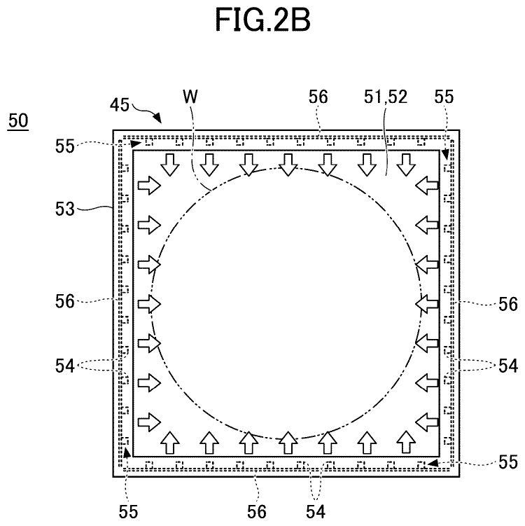

Next, the mounting table 45 that supports the wafer W and the irradiation device 50 that irradiates the wafer W with the test light will be described with reference to FIG. 2. FIG. 2A is a side cross-sectional view schematically illustrating the configuration of the mounting table 45 and the irradiation device 50. FIG. 2B is a plan view schematically illustrating the configuration of the mounting table 45 and the irradiation device 50.

As illustrated in FIG. 2A and FIG. 2B, the upper portion of the mounting table 45 has a stacked structure of the irradiation device 50 in which a diffusion section 51 and a light guide 52 are stacked in order from the mounting surface 45s of the wafer W toward the lower side in the vertical direction. The stacked structure of the diffusion section 51 and the light guide 52 is formed in a square shape larger than the diameter of the wafer w in plan view. Additionally, the stacked structure is installed on the upper surface of a table main body 47 of the mounting table 45 fixed to a movable body 44a (see FIG. 1) of the Z-axis movement mechanism 44. A temperature control mechanism 48 including a flow path through which a coolant circulates, a heater, and the like is provided in the table main body 47.

The diffusion section 51 supports the wafer W, and transmits and diffuses the test light guided from the light guide 52 to irradiate the wafer W with the test light. The diffusion section 51 includes a first glass plate 511 having the mounting surface 45s on which the wafer W is mounted, and a second glass plate 512 stacked on the lower side of the first glass plate 511. The first glass plate 511 is formed of, for example, porous glass. The second glass plate 512 is formed of, for example, low thermal expansion glass having a lower thermal expansion coefficient than porous glass. The lower surface of the first glass plate 511 and the upper surface of the second glass plate 512 are firmly fixed to each other by a glass adhesive (not illustrated).

The second glass plate 512 has a plate thickness greater than that of the first glass plate 511. A suction flow path 461 of the suction device 46 is formed inside the second glass plate 512, and the wafer W is vacuum-suctioned when the wafer W is mounted by the stage 40. The suction flow path 461 is formed in a lattice shape, a spiral shape, an annular shape, or the like along the surface direction (the horizontal direction) of the second glass plate 512, and the upper surface side thereof is opened.

In the stage 40, a main component of the suction device 46 is arranged outside the second glass plate 512 in the radial direction. Specifically, the suction device 46 includes a suction path 463 that communicates with the suction flow path 461 at the outer periphery of the second glass plate 512, a buffer tank 464 provided at an intermediate position of the suction path 463, and a vacuum pump 465 provided at a downstream portion of the suction path 463.

With respect to the above, the first glass plate 511 has a function of horizontally mounting the wafer W, a function of sticking the wafer W by suction, and a function of diffusing the test light directed to the wafer W. That is, the first glass plate 511 diffuses the test light inside to cause the entire surface of the mounting surface 45s to emit light. Additionally, the first glass plate 511 includes multiple through-holes 462 penetrating between the upper surface (the mounting surface 45s) and the lower surface. The through-holes 462 respectively communicate with the suction flow paths 461 of the second glass plate 512 on the lower layer side. The suction device 46 applies an appropriate negative pressure to each of the through-holes 462 via the suction path 463 and the suction flow path 461 by performing a suction operation of the vacuum pump 465 under the control of the controller 80 (see FIG. 1). This allows the stage 40 to transfer the wafer W with no position shift by sticking the wafer W to the mounting surface 45s by suction.

Here, the means of the stage 40 holding the wafer W is not limited to the above, and various configurations can be adopted. For example, the stage 40 may include a position shift preventing member (not illustrated) such as an O-ring in order to prevent the position of the wafer W from being shifted with respect to the mounting surface 45s. Additionally, the stage 40 may include a clamp (not illustrated) holding the outer periphery of the wafer W. Further, the stage 40 may include a protrusion (not illustrated) supporting the wafer W at the outer periphery of the mounting surface 45s, and may include a micro lens array (not illustrated) on the inner side of the protrusion in the radial direction. Additionally, a protective coating (not illustrated) for protecting the on-chip lenses of the image sensors of the wafer W may be formed on the upper surface of the first glass plate 511 of the stage 40.

The light guide 52 includes a light guide plate 521 that guides test light emitted from the outer side in the radial direction to the inner side and diffusely reflects the test light so that the entire plate surface can emit light, and a reflective layer 522 that is stacked on the lower surface (the surface opposite to the diffusion section 51) of the light guide plate 521. For example, the light guide plate 521 is formed of a glass plate containing an appropriate impurity. Additionally, the reflective layer 522 reflects the test light directed downward from the light guide 52 to the upper surface side.

The irradiation device 50 includes a light emission frame 53 formed such that side edges at four sides of the light guide 52 are inserted and the light emission frame 53 surrounds the side edges. As illustrated in FIG. 2B, the light emission frame 53 is configured to emit the test light to the side edges of the light guide 52 from four sides (the entire periphery).

Inside the light emission frame 53, a circuit board 56 is provided for each side of the light emission frame 53, and an LED module 55 (an LED array) in which multiple LEDs 54 are arranged is mounted on each of the circuit boards 56. That is, the irradiation device 50 includes four circuit boards 56 along the peripheral direction of the light emission frame 53. Each of the circuit boards 56 is arranged so that the multiple LEDs 54 (the LED module 55) are arranged in a line to face the side edge of the light guide 52. Further, a light shielding body 57 provided on the upper and lower surfaces at the side edge of the light guide 52 and blocking the test light emitted from each of the LEDs 54 from traveling toward a portion other than the light guide 52 is provided near the inner side of the light emission frame 53.

The LED module 55 of each of the circuit boards 56 functions as a light emitting section of the irradiation device 50, in which multiple LEDS 54 are connected in series. The number n of the LEDS 54 constituting the LED module 55 is not particularly limited, but may be in a range of, for example, about 10 to 100. In this case, the irradiation device 50 needs to output a forward voltage of n×Vf from a power supply to the LED module 55. Additionally, each of the LEDs 54 is a current control element, and the amount of light (the radiation intensity) is proportional to the current. In the test of the image sensor, in order for the light emitting section to output a target light amount (for example, 0.1 Lux to 100,000 Lux), it is necessary to supply a current from a low current to a high current and to adjust the current minutely. However, if a hard-switch power supply that simply switches between a high current and a high voltage is used as a power supply supplying power to the LED module 55, power loss becomes very large.

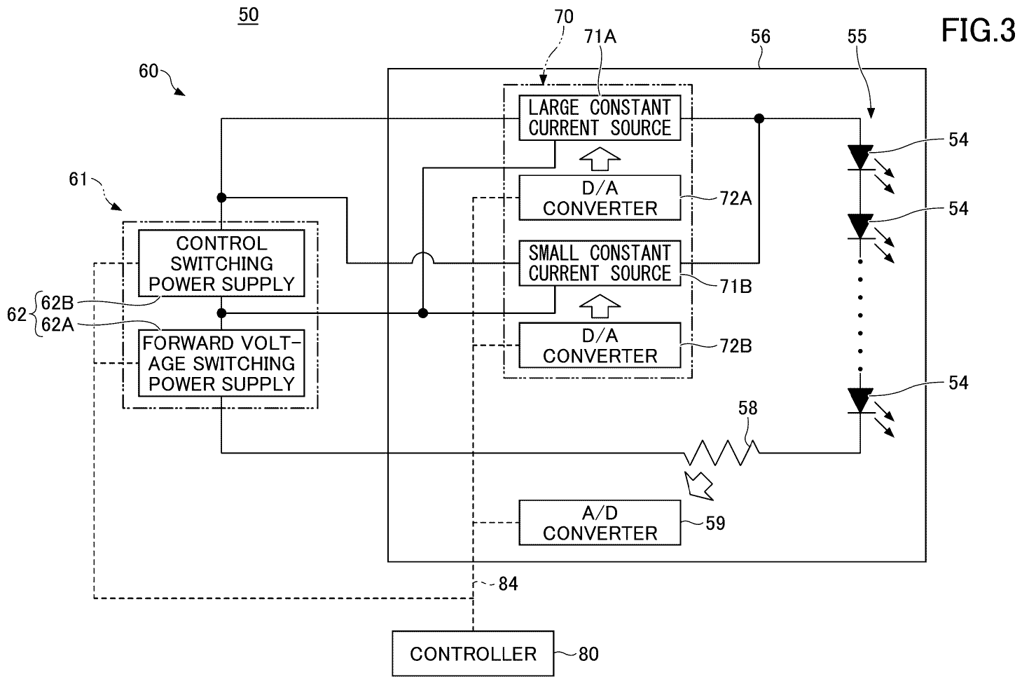

Thus, the irradiation device 50 according to the present embodiment realizes appropriate control of the voltage and the current with reduced power loss by a supply circuit 60 configured to supply power to the LED module 55. Next, the supply circuit 60 of the irradiation device 50 will be described with reference to FIG. 3. FIG. 3 is an explanatory view schematically illustrating a configuration of the supply circuit 60 of the irradiation device 50.

The supply circuit 60 includes the LED module 55, a fixed power supply 61, which is a power supply of the LED module 55, and a constant current section 70 provided between the LED module 55 and the fixed power supply 61 and configured to adjust the amount of the current. The fixed power supply 61 is installed, for example, on the side or inside of the mover 41 or in the stage controller 49, and supplies power to each of the circuit boards 56 of the light emission frame 53. The constant current section 70 is provided, for example, on each of the circuit boards 56.

The fixed power supply 61 employs a low-noise switching power supply 62 (a soft switching power supply) in order to reduce power loss due to switching. Additionally, the fixed power supply 61 has a configuration in which two switching power supplies 62 are connected in series. Specifically, the two switching power supplies 62 are a forward voltage switching power supply 62A configured to supply a forward voltage (n×Vf) to the constant current section 70, and a control switching power supply 62B configured to supply a current control voltage Vval to the constant current section 70.

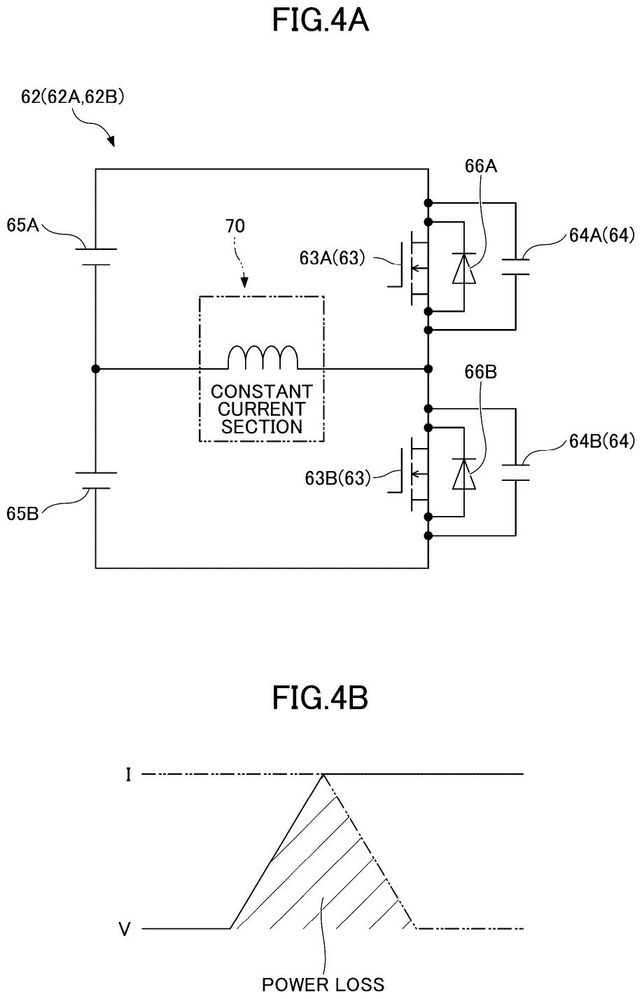

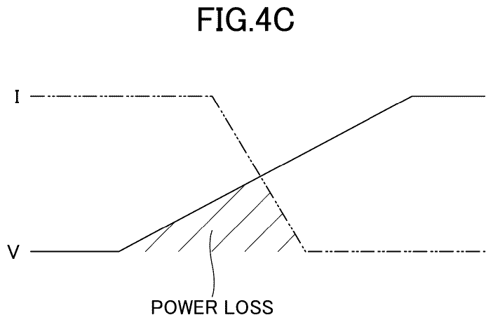

FIG. 4A is a circuit diagram illustrating a configuration of the switching power supply 62. FIG. 4B is a waveform diagram of a hard-switch power supply with no capacitor at turn-off. FIG. 4C is a waveform diagram of a hard-switch power supply with a capacitor at turn-off. As illustrated in FIG. 4A, each of the switching power supplies 62 employs a circuit structure of a ZVS (Zero Voltage Switching) in which switching is performed in a state where the voltage is zero. Each of the switching power supplies 62 is configured as an LC resonance circuit in which capacitors 64 are respectively connected in parallel to two switching elements 63 (for example, MOSFETs) and a load (the constant current section 70) is an inductance. In detail, each of the switching power supplies 62 includes two power supplies 65A and 65B and two switching elements 63A and 63B, which form a bridge. Then, in each of the switching power supplies 62, a capacitor 64A and a diode 66A are connected in parallel to the switching element 63A, and a capacitor 64B and a diode 66B are connected in parallel to the switching element 63B.

Here, in the case of a hard-switch power supply in which the capacitor 64 is not provided at the switching element 63, as illustrated in FIG. 4B, large power loss occurs when the current is turned off (in the period in which the current and the voltage are switched). With respect to the above, in each of the switching power supplies 62 of FIG. 4A, for example, when the switching element 63B is turned off, the current flowing through the switching element 63B is commutated to the capacitor 64B, and the voltage of the capacitor 64B gradually increases. Therefore, as illustrated in FIG. 4C, the slope of the voltage increase becomes slower in accordance with the capacitance of the capacitor 64B, and power loss decreases. When the switching element 63A is turned off, the charge of the capacitor 64B flows through the constant current section 70. At this time, when the switching element 63B is turned on, the voltage of the switching element 63B in the on state becomes substantially 0 V, to function as soft switching.

Returning to FIG. 3, the two switching power supplies 62 (the forward voltage switching power supply 62A and the control switching power supply 62B) output different voltages. The forward voltage switching power supply 62A outputs a voltage corresponding to the forward voltage Vf of each of the LEDs 54 constituting the LED module 55 and the number n of the LEDs, that is, a constant voltage of Vf×n. For example, when the forward voltage Vf of each of the LEDs 54 of the white color light is 2.7 V and the number n of the LEDs 54 is 10, the forward voltage switching power supply 62A outputs a voltage approximate to 27 V (=10×2.7). In other words, the forward voltage switching power supply 62A performs on/off duty control by soft switching so as to be substantially 27 V.

With respect to the above, the control switching power supply 62B outputs a constant current control voltage in the constant current section 70. The voltage output from the control switching power supply 62B is set to, for example, about 0.5 V for each of the LEDs 54, although depending on the characteristics and the number n of the LEDs 54 and the configuration of the constant current section 70. Therefore, when the number n of the LEDs 54 is 10, the control switching power supply 62B outputs a voltage approximate to 5 V (=10×0.5 V). In other words, the control switching power supply 62B performs on/off duty control by soft switching so as to be substantially 5 V.

Here, each of the switching power supplies 62 uses a resonance phenomenon between the voltage and the current to reduce power loss and improve efficiency, but cannot greatly change the duty of on and off of the current. Therefore, it is difficult to widen the range of the current in order to change the light amount of each of the LEDs 54. Because of this, the irradiation device 50 according to the present embodiment is configured to linearly adjust the amount of the current supplied to the LED module 55 by applying a dropper circuit to the constant current section 70 provided between the fixed power supply 61 and the LED module 55. In particular, the constant current section 70 according to the present embodiment uses two constant current sources (a large constant current source 71A and a small constant current source 71B) formed by dropper circuits, thereby adjusting the amount of the current supplied to each of the LEDs 54 in a wide range and minutely.

Although not specifically illustrated, the dropper circuit constituting each of the constant current sources of the constant current section 70 is configured by appropriately combining a transistor (including a MOSFET), an operational amplifier, a resistor, and the like. Here, the constant current source of the constant current section 70 may be an IC chip including elements and wiring of the dropper circuit inside, or may be configured by wiring various discrete devices on the circuit board 56.

For example, the dropper circuit causes the operational amplifier to function as a differential amplifier (a reference amplifier), and while the voltage of the forward voltage switching power supply 62A is input as a reference voltage, the voltage of the control switching power supply 62B is input as an input voltage. The output of the operational amplifier is connected to the base of the transistor, and the transistor functions as a control element that divides the input voltage. Additionally, the dropper circuit is connected to the controller 80 via the D/A converter 72, and changes a voltage division ratio (for example, a resistance value) of the input voltage in accordance with a command (a current command) of the controller 80 to adjust the amount of the current output from the dropper circuit.

In the dropper circuit configured as described above, in principle, switching noise does not occur, but heat is generated when the transistor serving as the control element divides the input voltage. However, as described above, the voltage of the control switching power supply 62B is input as the input voltage of the dropper circuit, and thus the heat generation of the transistor is suppressed in comparison with the voltage of the forward voltage switching power supply 62A. As a result, the irradiation device 50 can significantly reduce power loss in the constant current section 70.

For example, when each of the LEDs 54 is white, as described above, the voltage of the forward voltage switching power supply 62A is 27 V, and the voltage of the control switching power supply 62B is 5 V. Therefore, the irradiation device 50 can reduce power loss of the constant current section 70 to ⅕ or less of that in the case where the fixed power supply 61 is configured by one power supply.

The constant current section 70 is configured by connecting the large constant current source 71A and the small constant current source 71B having different resolutions in parallel to the LED module 55. For example, the large constant current source 71A is formed so that the current output from the large constant current source 71A can be adjusted with a resolution of 100 mA (100 mA or greater). That is, the large constant current source 71A adjusts the amount of the current in a unit of 100 mA based on the current command of the controller 80 received via a D/A converter 72A. With respect to the above, the small constant current source 71B is formed so that the current output from the small constant current source 71B can be adjusted with a resolution of 1 mA (less than 100 mA). That is, the small constant current source 71B adjusts the amount of the current in a unit of 1 mA based on the current command of the controller 80 received via a D/A converter 72B.

With this, the constant current section 70 can output a wide range of current to the LED module 55 by combining the large constant current source 71A and the small constant current source 71B. Specifically, the controller 80 determines distribution for the large constant current largely (roughly) adjusting the current amount and distribution for the small constant current finely (minutely) adjusting the current amount, and outputs a current command to each of the large constant current source 71A and the small constant current source 71B. This allows the constant current section 70 to supply the LED module 55 with the current having the sum of the amount of the current adjusted by the large constant current source 71A (the distribution for the large constant current) and the amount of the current adjusted by the small constant current source 71B (the distribution for the small constant current).

For example, when the current of 1.234 A is supplied to the LED module 55, the controller 80 causes the large constant current source 71A to output the current of 1.2 A and causes the small constant current source 71B to output the current of 0.034 A. By distributing the current in such a way, the irradiation device 50 can adjust a wide range of current in the constant current section 70 with high accuracy.

Additionally, the supply circuit 60 includes a resistor 58 connected in series with the LED module 55, and is configured such that the controller 80 reads an actual current flowing through the resistor 58 via an A/D converter 59. That is, the supply circuit 60 has a function of an ammeter configured to measure the actual current supplied to the LED module 55. For example, the controller 80 feeds back the actual current acquired from the resistor 58 in the adjustment of the current amount, thereby adjusting the amount of the current (in other words, the target light amount of the test light) supplied to the LED module 55 with high accuracy.

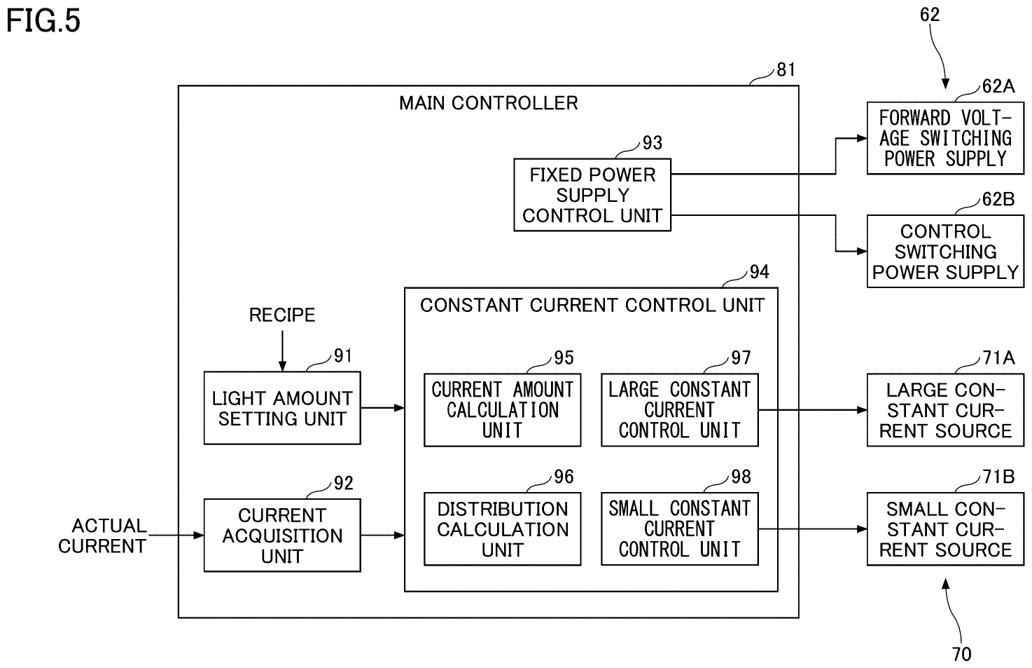

The components of the supply circuit 60 (the forward voltage switching power supply 62A, the control switching power supply 62B, the D/A converter 72A, the D/A converter 72B, and the A/D converter 59) and the controller 80 are configured to transmit and receive signals via a serial bus 84. The controller 80 constructs functional blocks as illustrated in FIG. 5 by the processor 82 executing a program stored in the memory 83, and controls the operation of the irradiation device 50 during the test of the wafer W. FIG. 5 is a block diagram illustrating functional blocks of the main controller 81 configured to control the irradiation device 50.

Specifically, a light amount setting unit 91, a current acquisition unit 92, a fixed power supply control unit 93, and a constant current control unit 94 are formed inside the main controller 81.

The light amount setting unit 91 sets the light amount (the radiation intensity) of the test light emitted from the multiple LED modules 55 provided in the light emission frame 53 based on the test content (the recipe) of the wafer W. Here, the light amount of the test light may be set by a user via the user interface 85 (see FIG. 1).

The current acquisition unit 92 acquires the actual current supplied to each of the LED modules 55 via the resistor 58 and the A/D converter 59 provided in the supply circuit 60, and outputs the acquired actual current to the constant current control unit 94.

The fixed power supply control unit 93 controls the timing of outputting power and switching of each of the switching power supplies 62 (the forward voltage switching power supply 62A and the control switching power supply 62B). As described above, the irradiation device 50 according to the present embodiment adjusts the amount of the current in the constant current section 70. Thus, the fixed power supply control unit 93 performs switching of the forward voltage Vf×n corresponding to the LED module 55 in the forward voltage switching power supply 62A without depending on the control of the amount of the current supplied to the LED module 55. Additionally, the fixed power supply control unit 93 performs switching of the current control voltage Vval output to the constant current section 70 in the control switching power supply 62B without depending on the control of the amount of the current supplied to the LED module 55.

The constant current control unit 94 calculates the amount of the current to be supplied to each of the LED modules 55 based on the light amount set by the light amount setting unit 91, and controls the operation of the constant current section 70 based on the calculated amount of the current. Therefore, the constant current control unit 94 includes a current amount calculation unit 95, a distribution calculation unit 96, a large constant current control unit 97, and a small constant current control unit 98 inside.

The current amount calculation unit 95 calculates the amount of the current to be supplied to each of the LED modules 55 based on the light amount of the test light set by the light amount setting unit 91. For example, the current amount calculation unit 95 stores map information in which the light amount of the test light and the amount of the current are associated with each other in the memory 83 in advance, and extracts the current amount corresponding to the light amount with reference to the map information when receiving the light amount of the test light from the light amount setting unit 91. Alternatively, the current amount calculation unit 95 may have a function that associates the light amount of the test light with the current amount, and may calculate the current amount by using the light amount of the test light and the predetermined function.

The distribution calculation unit 96 appropriately distributes the amount of the current supplied from the large constant current source 71A to the LED module 55 and the amount of the current supplied from the small constant current source 71B to the LED module 55 based on the current amount calculated by the current amount calculation unit 95. As described above, the distribution calculation unit 96 distributes the current amount so that the current amount is adjusted by the large constant current source 71A when the calculated current amount is 100 mA or greater, and the current amount is adjusted by the small constant current source 71B when the calculated current amount is less than 100 mA.

Then, the large constant current control unit 97 instructs the current amount of the large constant current source 71A distributed by the distribution calculation unit 96 to the large constant current source 71A via the D/A converter 72A. The dropper circuit of the large constant current source 71A adjusts the current amount based on the current command and supplies the current to the LED module 55. Similarly, the small constant current control unit 98 instructs the current amount of the small constant current source 71B distributed by the distribution calculation unit 96 to the small constant current source 71B via the D/A converter 72B. The dropper circuit of the small constant current source 71B adjusts the current amount based on the current command and supplies the current to the LED module 55.

Additionally, the constant current control unit 94 adjusts the current amount to be instructed to the large constant current source 71A and the small constant current source 71B by using the actual current acquired by the current acquisition unit 92, and outputs a current instruction so that the actual current matches the target current amount. This allows the main controller 81 to control the light amount of the test light emitted by the irradiation device 50 with higher accuracy.

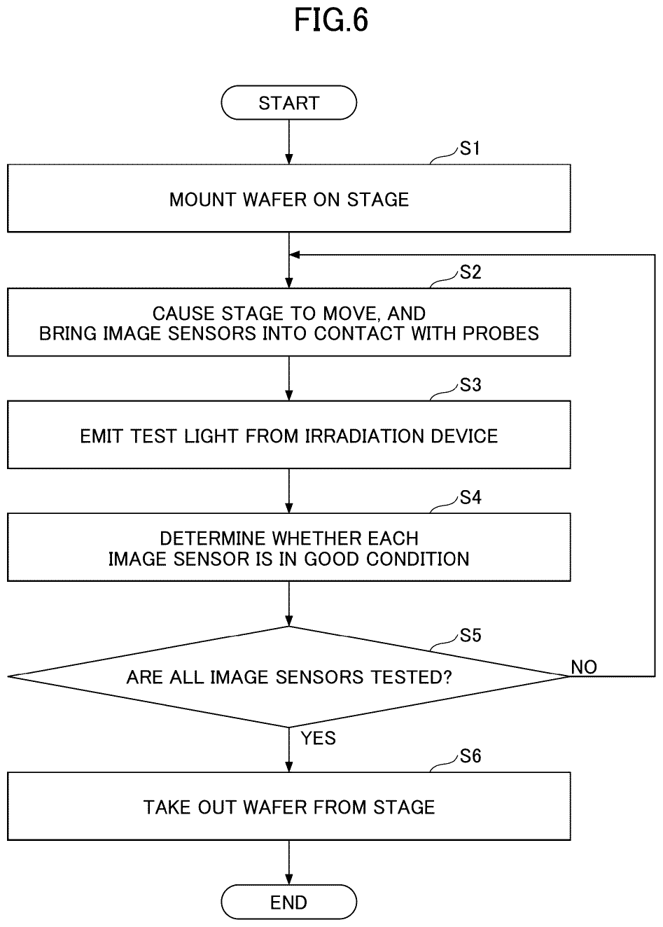

The test device 1 according to the present embodiment is basically configured as described above, and an operation (a test method) thereof will be described below. FIG. 6 is a flowchart illustrating a test method according to the embodiment.

As illustrated in FIG. 6, in the test of the wafer W, the controller 80 of the test device 1 first mounts the wafer W on the stage 40 from the loader 10 (step S1). When the wafer W is mounted on the stage 40, the controller 80 drives the suction device 46 to stick the wafer W to the mounting surface 45s by suction.

Next, the controller 80 moves the stage 40 in the horizontal direction to make the image sensors of the wafer W to be tested respectively face the probes 33, and further raises the stage 40 to bring the probes 33 into contact with the wiring layers of the image sensors, respectively (step S2). After the contact of each of the probes 33, the test device 1 transmits an operation command from the controller 80 to the tester 30 and the irradiation device 50 to start the optical test of each of the image sensors. For example, the tester 30 outputs bias voltages to the image sensors via the probes 33 to activate the image sensors.

In the optical test, the controller 80 emits the test light having the set light amount from the light emission frame 53 to the light guide 52 (step S3). As illustrated in FIG. 2A, the test light entering the four side edges of the light guide 52 from the light emission frame 53 travels while being diffusely reflected in the light guide 52, and thus travels from the entire plate surface of the light guide 52 toward the diffusion section 51. Further, the test light is diffused and transmitted in the diffusion section 51, and is received by the picture elements (photodiode) of the image sensors of the wafer W through the mounting surface 45s.

Here, the irradiation device 50 can emit the test light having the light amount appropriately adjusted by the supply circuit 60. Specifically, as illustrated in FIG. 5, the fixed power supply control unit 93 causes the forward voltage switching power supply 62A and the control switching power supply 62B to operate, so that the fixed power supply 61 outputs the forward voltage Vf×n and the current control voltage Vval, which are synchronized with each other, to the constant current section 70.

At this time, each of the switching power supplies 62 (the forward voltage switching power supply 62A and the control switching power supply 62B) performs soft switching as described above (see FIG. 4A and FIG. 4B). This allows the fixed power supply 61 to suppress power loss due to switching and reduce noise of the output power. The forward voltage switching power supply 62A can output a substantially constant forward voltage Vf×n to the large constant current source 71A and the small constant current source 71B. Additionally, the control switching power supply 62B can output a substantially constant current control voltage Vval to the large constant current source 71A and the small constant current source 71B.

With respect to the above, the light amount setting unit 91 sets the light amount of the test light based on the recipe in the optical test. The constant current control unit 94 outputs a current command to each of the large constant current source 71A and the small constant current source 71B based on the set light amount of the test light and the actual current acquired by the current acquisition unit 92.

As illustrated in FIG. 3, the large constant current source 71A that has received the current command via the D/A converter 72A outputs the current amount distributed by the current command based on the input forward voltage Vf×n and the current control voltage Vval. Additionally, the small constant current source 71B that has received the current command via the D/A converter 72B outputs the current amount distributed by the current command based on the input forward voltage Vf×n and the current control voltage Vval. As described above, the control elements of the large constant current source 71A and the small constant current source 71B generate heat in accordance with the current control voltage Vval, but the amount of the heat generation is suppressed because the voltage is small. As a result, power loss in the constant current section 70 can be suppressed.

The constant current section 70 can control the amount of the current supplied to the LED module 55 in a wide range and minutely by applying two systems of the large constant current source 71A and the small constant current source 71B. This allows the supply circuit 60 to emit the test light having the target light amount from each of the LEDs 54 of the LED module 55 with high reproducibility.

Returning to FIG. 6, the tester 30 of the test device 1 acquires an electric signal corresponding to the light amount of the test light of the irradiation device 50 from the image sensors of the wafer W via the probes 33 and the probe card 32, and determines whether each of the image sensors is in a good condition or not (step S4). Specifically, the tester 30 tests the presence or absence of a defect in each of picture elements of each of the image sensors based on the acquired electrical signal.

The optical test of the image sensor is performed by changing the light amount of the test light of the irradiation device 50 multiple times. In this case, the constant current control unit 94 changes the current commands to the large constant current source 71A and the small constant current source 71B based on the distribution calculated by the distribution calculation unit 96, thereby appropriately changing the amount of the current output from the constant current section 70. The constant current section 70 can adjust the light amount of the test light to the changed target light amount with high accuracy by adjusting the current amount minutely by the combination of the large constant current source 71A and the small constant current source 71B.

The controller 80 determines whether the optical test has been performed on all of the multiple image sensors of the wafer W after the optical test of each of the currently tested image sensors (step S5). If there is an untested image sensor, the process returns to step S2, the stage 40 is moved to bring the untested image sensor into contact with the probe 33, and the operations of steps S3 and S4 are repeated. If the test is completed for all of the multiple image sensors of the wafer W, the process proceeds to step S6.

In step S6, the stage 40 is moved and the tested wafer W is taken out by the loader 10 from the stage 40, and the test is finished.

By performing the test method described above, the test device 1 can stably irradiate the wafer W with the test light having the target light amount while reducing power loss and noise of the irradiation device 50. This allows the test device 1 to test the image sensors of the wafer W with high accuracy and quickly. Therefore, for example, the test device 1 can suppress a disadvantage such as overlooking a defect of each of the picture elements of the image sensors in the test.

Here, the configuration of the test device 1 is not limited to the embodiment described above, and various modifications can be made, naturally. For example, the irradiation device 50 is an edge type including the LED module 55 in the light emission frame 53 on the side of the mounting table 45, but may be a direct type including the LED module 55 in the mounting table 45 in the stacking direction of the mounting surface 45s. Additionally, the irradiation device 50 according to the embodiment described above is configured to irradiate the test light of a single color (white), but is not limited thereto, and may be configured to irradiate the test light of multiple colors (for example, RGB).

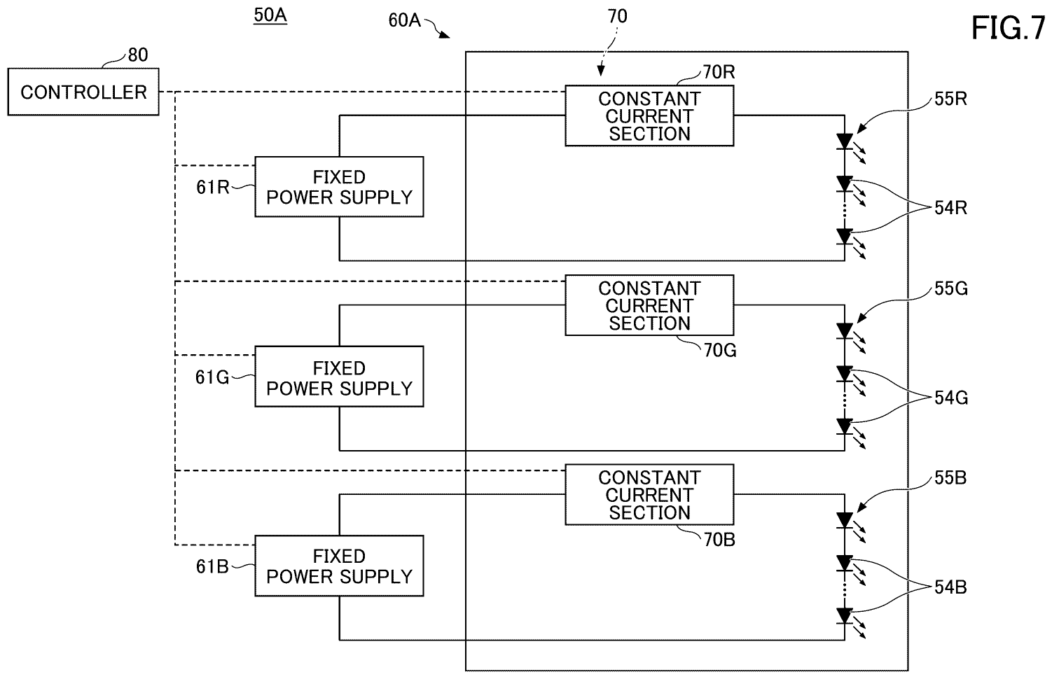

FIG. 7 is an explanatory diagram schematically illustrating a supply circuit 60A of an irradiation device 50A according to a modified example. As illustrated in FIG. 7, the irradiation device 50A configured to irradiate the test light of each of RGB includes a supply circuit 60A configured to irradiate the test light, for each of the multiple circuit boards 56 (see FIG. 2B) provided in the light emission frame 53. The supply circuit 60A includes an LED module 55R including multiple red LEDs 54R, an LED module 55G including multiple green LEDs 54G, and an LED module 55B including multiple blue LEDs 54B on each of the circuit boards 56. The LED modules 55R, 55G, and 55B may be installed so as to extend linearly along the extending direction of the side edge of the light guide 52 and to be parallel to each other.

The supply circuit 60A includes a fixed power supply 61R and a constant current section 70R to supply power to the LED module 55R, a fixed power supply 61G and a constant current section 70G to supply power to the LED module 55G, and a fixed power supply 61B and a constant current section 70B to supply power to the LED module 55B. Each of the fixed power supplies 61R, 61G, and 61B is configured by the forward voltage switching power supply 62A and the control switching power supply 62B, as the fixed power supply 61 of FIG. 3 is. Each of the constant current sections 70R, 70G, and 70B is also configured by the large constant current source 71A and the small constant current source 71B, as the constant current section 70 illustrated in FIG. 3 is.

Here, the forward voltage Vf of the red LED 54R may be a value less than the forward voltage Vf of the green LED 54G or the blue LED 54B, and may be set to, for example, 1.8 V. Thus, the forward voltage switching power supply 62A of the fixed power supply 61R supplies 18 V as the forward voltage Vf×n when the LED module 55R is ten red LEDs 54. Therefore, the voltage (for example, 5 V) of the control switching power supply 62B supplied to the constant current section 70 is set to a ratio of 5/18 (that is, ⅓ or less) with respect to the voltage of the forward voltage switching power supply 62A. Even in this case, the heat generation of the control element of the constant current section 70 is sufficiently suppressed, and power loss can be reduced.

The supply circuit 60A configured as described above can adjust the light amount of each of the RGB test light beams with high accuracy and can emit the light with power loss, noise, and the like being reduced.

Therefore, the test device 1 can perform the test with high accuracy and efficiency even when testing the image sensors of the wafer W by using test light of multiple colors.

The technical ideas and effects of the present disclosure described in the above embodiments will be described below.

The first aspect of the present disclosure is the test device 1 configured to test the substrate (the wafer W) and includes the mounting table 45 on which the substrate is mounted, the irradiation device 50 provided in the mounting table 45 and configured to irradiate the substrate mounted on the mounting table 45 with the test light, and the tester 30 configured to test the substrate that has received the test light. The irradiation device 50 includes a light emitting section (the LED module 55) in which multiple LEDs 54 are connected to each other, the fixed power supply 61 configured to output the power to be supplied to the light emitting section, and the constant current section 70 provided between the light emitting section and the fixed power supply 61 and configured to adjust the current amount based on the voltage input from the fixed power supply 61 and supply the current to the light emitting section. The fixed power supply 61 includes multiple switching power supplies 62 configured to perform switching using a resonance phenomenon. The constant current section 70 includes a first constant current source (the large constant current source 71A) configured to receive the power of the multiple switching power supplies 62 and adjust the current supplied to the light emitting section in a first resolution, and a second constant current source (the small constant current source 71B) configured to receive the power of the multiple switching power supplies 62 and adjust the current supplied to the light emitting section in a second resolution less than the first resolution, that are connected in parallel.

According to the above description, the test device 1 can significantly reduce power loss of switching by applying the switching power supplies 62 using the resonance phenomenon to the fixed power supply 61. Moreover, the test device 1 can adjust the light amount of the light to be emitted in a wide range with high accuracy by including the first constant current source (the large constant current source 71A) configured to adjust the current in the first resolution and the second constant current source (the small constant current source 71B) configured to adjust the current in the second resolution in the constant current section 70. This allows the test device 1 to satisfactorily test the substrate (the wafer W), and promote improvement, efficiency, and the like in test accuracy of the substrate.

Additionally, the fixed power supply 61 includes, as the multiple switching power supplies 62, the forward voltage switching power supply 62A configured to output a voltage approximate to the sum of the forward voltages of the multiple LEDs 54, and the control switching power supply 62B configured to output a voltage for controlling the currents of the first constant current source (the large constant current source 71A) and the second constant current source (the small constant current source 71B). This allows the test device 1 to output a constant forward voltage and a constant current control voltage while suppressing power loss and noise in the fixed power supply 61, and stably adjust the current in the constant current section 70.

Additionally, the voltage output by the control switching power supply 62B is set to be ⅓ or less of the voltage output by the forward voltage switching power supply 62A. This allows the test device 1 to suppress heat generated in the control element of the constant current section 70 as much as possible and adjust the current.

Additionally, the first constant current source (the large constant current source 71A) can adjust the current in a unit greater than or equal to 100 mA as the first resolution, and the second constant current source (the small constant current source 71B) can adjust the current in a unit less than 100 mA as the second resolution. This allows the test device to adjust the light amount of the light emitting section in a wider range and more minutely.

Additionally, the controller (the controller 80) configured to control the irradiation device 50 is included, the controller is communicably connected to each of the first constant current source (the large constant current source 71A) and the second constant current source (the small constant current source 71B) via the D/A converters 72A and 72B, and the first constant current source and the second constant current source adjust the currents according to the current commands output from the controller. This allows the test device 1 to easily adjust the currents in the first constant current source and the second constant current source based on the control of the controller.

Additionally, the controller (the controller 80) calculates the total amount of the current supplied to the light emitting section based on the light amount of the light emitting section (the LED module 55) set in the test of the substrate (the wafer W), and sets the distribution of the amount of the current output from the first constant current source (the large constant current source 71A) and the amount of current output from the second constant current source (the small constant current source 71B), based on the total amount of the current. This allows the test device 1 to appropriately distribute the adjustment of the current in the first constant current source and the second constant current source.

Additionally, the resistor 58 connected in series with the light emitting section (the LED module 55) is included, and the controller (the controller 80) acquires the actual current flowing through the resistor 58 via the A/D converter 59 and adjusts the entire current amount based on the acquired actual current. This allows the test device 1 to adjust the current based on the actual current actually flowing through the light emitting section, and satisfactorily reproduce the light amount of the irradiation device 50 to match the target light amount.

Additionally, the irradiation device 50 can emit light of different colors for each of the multiple light emitting sections (the LED modules 55), and includes the fixed power supply 61 and the constant current section 70 for each of the multiple light emitting sections. With this, even when performing the test with multiple colors, the test device 1 can simply and accurately emit the test light having the target light amount while suppressing power loss.

The irradiation device 50 includes the light guide 52 facing the mounting surface 45s of the mounting table 45 and the frame (the light emission frame 53) surrounding the entire periphery of the side edge of the light guide 52, and includes the circuit board 56 including the light emitting section (the LED module 55) and the constant current section 70 inside the frame. This allows the test device 1 to irradiate the entire light guide 52 with the test light from the surrounding frame, and cause the test light having the target light amount to enter the substrate (the wafer W).

Additionally, the second aspect of the present disclosure is the test method of the test device for testing the substrate (the wafer W), and includes (a) a step of mounting the substrate on the mounting table 45; (b) a step of irradiating the substrate mounted on the mounting table 45 with the test light by the irradiation device 50 provided in the mounting table 45; and (c) a step of testing the substrate that receives the test light by the tester 30.

Step (b) includes outputting the power to be supplied to the light emitting section (the LED module 55) in which multiple LEDs 54 are connected, by the fixed power supply 61 including multiple switching power supplies 62 configured to perform switching using a resonance phenomenon, and supplying, to the light emitting section, the current adjusted based on the voltage input from the fixed power supply 61 by the constant current section 70 provided between the emitting section and the fixed power supply 61. The constant current section 70 includes the first constant current source (the large constant current source 71A) and the second constant current source (the small constant current source 71B) connected in parallel, receives the power of multiple switching power supplies 62 in the first constant current source and adjusts the current supplied to the light emitting section in the first resolution, and receives the power of multiple switching power supplies 62 in the second constant current source and adjusts the current supplied to the light emitting section in the second resolution less than the first resolution. Even in this case, the test method can suppress power loss of the irradiation device 50 and can adjust the light amount in a wide range with high accuracy in the test of the substrate.

Additionally, in the present description, the control switching power supply 62B is shared by the large constant current source 71A and the small constant current source 71B, but the control switching power supply 62B may be divided for the large constant current source 71A and the small constant current source 71B for improving power efficiency.

The test device 1 and the test method according to the embodiments disclosed herein are merely examples in all respects and are not restrictive. The embodiments can be modified and improved in various forms without departing from the scope and spirit of the appended claims. The matters described in the embodiments described above can also take other configurations as long as there is no contradiction, and can be combined as long as there is no contradiction.

This application claims priority to Japanese Patent Application No. 2022-056610 filed on Mar. 30, 2022, the entire contents of which are incorporated herein by reference.

### DESCRIPTION OF REFERENCE SYMBOLS

1 test device
30 tester
45 mounting table
50 irradiation device
54 LED
55 LED module
61 fixed power supply
62 switching power supply
70 constant current section
71A large constant current source
71B small constant current source
W wafer

1. A test device for testing a substrate, the test device comprising:
a mounting table configured to mount the substrate;
an irradiation device provided in the mounting table and configured to irradiate the substrate mounted on the mounting table with test light; and
a tester configured to test the substrate that has received the test light,
wherein the irradiation device includes:
a light emitting section in which a plurality of LEDs are connected;
a fixed power supply configured to output power to be supplied to the light emitting section; and
a constant current section provided between the light emitting section and the fixed power supply and configured to adjust an amount of a current based on a voltage input from the fixed power supply and supply the current to the light emitting section,
wherein the fixed power supply includes a plurality of switching power supplies configured to perform switching using a resonance phenomenon, and
wherein the constant current section includes a first constant current source and a second constant current source connected in parallel, the first constant current source being configured to receive the power of the plurality of switching power supplies and adjust a current to be supplied to the light emitting section in a first resolution, and the second constant current source being configured to receive the power of the plurality of switching power supplies and adjust a current to be supplied to the light emitting section in a second resolution less than the first resolution.

2. The test device as claimed in claim 1, wherein the fixed power supply includes, as the plurality of switching power supplies, a forward voltage switching power supply configured to output a voltage approximate to a sum of forward voltages of the plurality of LEDs and a control switching power supply configured to output a current control voltage of the first constant current source and the second constant current source.

3. The test device as claimed in claim 2, wherein the voltage output by the control switching power supply is set to ⅓ or less of the voltage output by the forward voltage switching power supply.

4. The test device as claimed in claim 1,
wherein the first constant current source is configured to adjust the current in a unit of 100 mA or greater as the first resolution, and
wherein the second constant current source is configured to adjust the current in a unit less than 100 mA as the second resolution.

5. The test device as claimed in claim 1, further comprising a controller configured to control the irradiation device,
wherein the controller is communicably connected to each of the first constant current source and the second constant current source via a D/A converter, and
wherein the first constant current source and the second constant current source adjust the current in accordance with a current command output from the controller.

6. The test device as claimed in claim 5, wherein the controller calculates a total amount of a current to be supplied to the light emitting section based on a light amount of the light emitting section that is set in the test of the substrate, and sets distribution of an amount of the current output from the first constant current source and an amount of the current output from the second constant current source based on the total amount of the current.

7. The test device as claimed in claim 6, further comprising a resistor connected in series with the light emitting section,
wherein the controller acquires an actual current flowing through the resistor via an A/D converter and adjusts the total amount of the current based on the acquired actual current.

8. The test device as claimed in claim 1,
wherein the irradiation device is configured to emit light of different colors at a plurality of said light emitting sections, and
wherein the fixed power supply and the constant current section are provided for each of the plurality of light emitting sections.

9. The test device as claimed in claim 1,
wherein the irradiation device includes:
a light guide facing a mounting surface of the mounting table; and
a frame that surrounds a side edge of the light guide over an entire periphery thereof,
wherein a circuit board including the light emitting section and the constant current section is provided inside the frame.

10. A test method of a test device for testing a substrate, the test method comprising:
(a) mounting the substrate on a mounting table;
(b) a step of irradiating the substrate mounted on the mounting table with test light by an irradiation device provided in the mounting table; and
(c) testing the substrate that has received the test light by a tester,
wherein (b) includes outputting power to be supplied to a light emitting section, in which a plurality of LEDs are connected, by a fixed power supply including a plurality of switching power supplies configured to perform switching using a resonance phenomenon, and supplying, to the light emitting section, a current adjusted based on a voltage input from the fixed power supply by a constant current section provided between the light emitting section and the fixed power supply, and
wherein the constant current section includes a first constant current source and a second constant current source connected in parallel, the first constant current source receives the power of the plurality of switching power supplies and adjusts a current to be supplied to the light emitting section in a first resolution, and the second constant current source receives the power of the plurality of switching power supplies and adjusts a current to be supplied to the light emitting section in a second resolution less than the first resolution.
